(19) United States
(12) Patent Application Publication
(10) Pub. No.: US 2006/0226497 A1
(43) Pub. Date: Oct. 12, 2006

(54) Vertical nanotransistor, method for producing the same and memory assembly

(76) Inventors: Jle Chen, Berlin (DE); Rolf Koenekamp, Portland, OR (US)

Correspondence Address: LAW OFFICES OF KARL HORMANN, 86 SPARKS STREET, CAMBRIDGE, MA, 02138, US

(21) Appl. No.: 10/568,937

(22) PCT Filed: Aug. 16, 2004
(86) PCT No.: PCT/DE04/01839

§ 371 Date: Feb. 21, 2006

(30) Foreign Application Priority Data
Aug. 21, 2003 (DE) 103 39 529.6

(51) Int. Cl. H01L 29/76; H01L 29/94; H01L 31/00

(52) U.S. Cl. 257/401

(57) ABSTRACT

A vertical nano-transistor having a source contact, a drain contact, a gate region and a semiconductor cylindrical channel region between the source contact and the drain contact, the cylindrical channel region being embedded in a flexible insulating substrate and in the upper section of the channel region, in such a manner that the gate region and the upper section of the channel region form a coaxial structure and that the source contact, the semiconductor channel region and the drain contact are disposed vertically and the gate region is electrically insulated from the source contact, the drain contact and the semiconductor channel region and the upper surface and lower surface of the substrate are provided with an electrical insulation. The invention also relates to a memory assembly which consists of a plurality of vertical nano-transistors of the above-mentioned type, and to a method of fabricating the same.

### BACKGROUND OF THE INVENTION

1. Field of the Invention

The invention relates to a vertical nano-transistor, a method of its fabrication and a memory arrangement.

2. The Prior Art.

German patent specification DE 101 42 914 A1 describes a transistor arrangement which is highly resistant against mechanical stresses by bending, shearing or extension in which semiconductor material is vertically introduced into micro-holes of a film composite consisting of two plastic films and an intermediate metal layer. The semiconductor material is provided with metallic contacts at the upper and lower surface of the composite film. In this context, however, it is no easy matter to apply a metal layer on a plastic film; moreover, the method of fabricating such a vertical transistor arrangement embraces a plurality of method steps.

The vertical nano-transistor described in US 2002/0001905 also is complex and complicated in its fabrication, since initially a source region has to be applied to an expensive semiconductor substrate which is not flexible, and an insulating layer has to be applied to the source region. Holes in the nm-range are provided in the insulating layer (Al₂O₃ or Si), and vertically disposed carbon nano-tubes are placed in these holes. The gate region is arranged above the insulating layer around the carbon nano-tubes and is filled with a non-conductive material up to the upper covering surface of the nano-tubes. The formation of the gate region around the nano-tubes and maintaining these nano-tubes at identical diameters while they are being filled has shown itself to be very difficult. This may result in vertical transistor arrangements which because of different diameters of the associated nano-tubes also have different characteristics.

Engelhardt and Koenenkamp reported on the possibility, in J. Appl. Phys., Vol. 90, No. 8, 15 Oct. 2001, pp. 4287-4289, to fill holes formed in a polymeric film by ion irradiation followed by etching with CuSCN. The holes are of a diameter of 30 to 3,000 nm and are not formed over the entire thickness (22 μ m) of the polymeric film. A functioning components of such a channel structure has not been described.

In the vertical transistor described in DE 101 30 766 A1, the source region, the channel region and the drain region are disposed in a vertical direction. The gate region insulated from the source, drain and channel region, embraces the channel region and forms a coaxial structure. While it was possible in the fabrication of this arrangement to reduce the outlay in terms of time and machinery, the arrangement showed but poor resistance against mechanical stresses such as shearing and bending.

### OBJECT OF THE INVENTION

It is, therefore, an object of the invention to provide a vertical nano-transistor of high resistance against mechanical stresses and of less complexity in its fabrication than has been known in the prior art. In addition, a method of fabrication and a memory arrangement are to be provided.

### SUMMARY OF THE INVENTION.

In accordance with the invention, the object is accomplished by the vertical nano-transistor being provided with a source contact, a drain contact, a gate region and a cylindrical semiconductor channel region between the source and the drain contact, with the cylindrical channel region being embedded in a flexible insulating substrate and enclosed by the gate region formed by a metal layer on the flexible insulating substrate and the upper portion of the channel region such that the gate region and the upper section of the channel region form a coaxial structure, the source contact, the semiconductor channel region and the drain contact being arranged in a vertical direction, with the gate region being electrically insulated from the source contact, the drain contact and the semiconductor channel region and the upper and lower surfaces of the flexible substrate being provided with an electrical insulation.

The arrangement in accordance with the invention may be fabricated as a robust structure withstanding mechanical stresses without nano-lithographical steps. This is made possible by the embedding of the nano-structure in a flexible substrate. It avoids the complicated application of a large-surface metal layer on a plastic film. It is also not necessary to combine individual films to a composite film as in the arrangement of DE 101 42 913 A1.

Embodiments of the invention provide for cylindrically structuring the semiconductor channel region. The diameter of the semiconductor channel region amounts to several ten to several hundred nanometers. The material of the semiconductor channel region is CuSCN which allows application at room temperature, or TiO₂ or PbS or ZnO or another compound semiconductor.

Other embodiments relate to the insulation material, whether organic or inorganic, which at the upper and lower surface of the flexible substrate has a thickness of several micrometers and, in the penetrating holes in the flexible substrate, a thickness of several ten nanometers. While an insulating layer at the lower surface of the flexible insulating substrate is not required for the functioning of the arrangement in accordance with the invention, it does not act in a disturbing manner either if applied for technological reasons.

The coaxial arrangement of the cylindrical semiconductor channel region with the insulating material enclosing it, is embedded in the flexible insulating substrate the thickness of which is several ten micrometers and which is preferably a polymeric film.

Furthermore, the material provided for the source and drain contact is Au or Ag or Cu or Ni or Al and the source contact is structured in a dotted pattern.

The memory arrangement in accordance with the invention is provided with a plurality of vertical nano-transistors structured according to claim 1 adjacent each other in a memory matrix. The density of the holes formed in the flexible insulating substrate for forming the coaxial structure is very high.

In the method in accordance with the invention of fabricating a vertical nano-transistor having the characteristics according to claim 1, holes are initially formed in a flexible insulating substrate, thereafter a metal layer forming a gate is applied to the flexible insulation substrate and in the upper portion of the penetrating holes, followed by applying an insulating material to the formed structure. Hence, the insulation material is provided on the upper surface covered by the metal layer, on the lower surface of the flexible substrate and in the holes across the entire thickness of the of the flexible insulating substrate. Thereafter, a drain contact is mounted on the insulating lower surface of the flexible substrate. As has already been mentioned, the insulation layer is not required for the functioning. The drain contact may also be directly applied to the lower surface of the flexible insulating substrate. Semiconductor material is filled into the holes of the flexible substrate and, as a final step, the resultant semiconductor channel region is provided with a source contact.

Embodiments of the invention provide for forming the holes in the flexible substrate by ion beam irradiation followed by etching (see, for instance, the 3^{rd} Siberian Russian Workshop and Tutorials EDM'2002, Section 1, 1-5 July, Erlagol, pp. 31 or—as already mentioned—J. Appl. Phys., Vol. 90, No. 8, 15 Oct. 2001, pp. 4287-4289.

The flexible insulation substrate used, for instance, a polymeric film, is of a thickness of several ten micrometers.

An organic or inorganic material is used for the insulation layer. The organic material may be applied by vacuum filtration of a polymer solution.

In one embodiment of the invention the metal layer forming the gate is applied by vapor deposition, preferably from above at an angle.

The semiconductor material is introduced into the insulated holes by electrochemical bath precipitation or by chemical deposition or by the ILGAR process. The material used is CuSCN or TiO₂ or PbS or ZnO or another compound semiconductor.

The material provided for the drain and the source contact is Ag or Au or Ni or Al.

The application of the drain contact is carried out by electro deposition or chemical deposition or vapor deposition.

The method of fabrication of the vertical nano-transistor arrangement in accordance with the invention may be performed easily and adapts itself to the known thin-film technologies. Because of the arrangement in accordance with the invention there is no longer any need for limiting the fabrication process to predetermined temperatures.

### DESCRIPTION OF THE DRAWINGS

The novel features which are considered to be characteristic of the invention are set forth with particularity in the appended claims. The invention itself, however, in respect of its structure, construction and lay-out, as well as manufacturing techniques, together with other objects and advantages thereof, will be best understood from the following description when read with reference to the drawings, in which:

FIG. 1 depicts fabrication steps of nano-transistors in accordance with the invention which are embedded in a flexible insulating polymeric film;

FIG. 2 depicts current-voltage curves for an arrangement with about 2,000 nano-transistors in accordance with the invention.

### DETAILED DESCRIPTION OF THE PREFERRED EMBODIMENTS

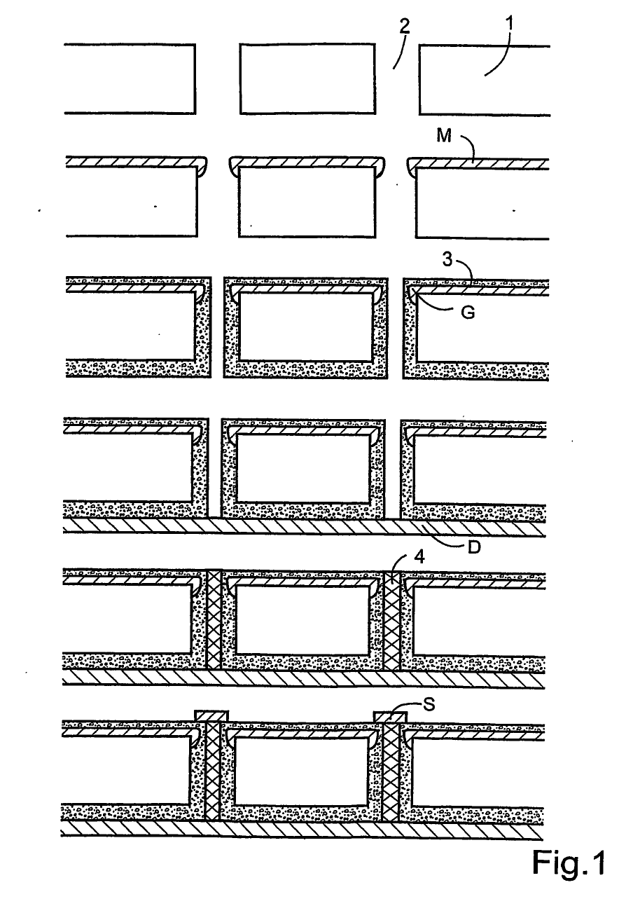

The individual method steps for fabricating vertical nano-transistors in accordance with the invention are shown in FIG. 1. Initially, holes 2 of a diameter of 200 nm are formed in a flexible insulating substrate 1, e.g. a polymeric film of 20 μm thickness, by ion bombardment and subsequent etching. Thereafter, the metal layer M, e.g. Au, forming the gate G is applied by oblique vapor deposition on the upper surface of the flexible insulating substrate 1 and deposited on the walls at the upper region of the holes 2. Thereafter, an organic insulating material, for instance, polystyrene, is applied by vacuum filtration of a polymer solution such the wall of the holes 2 and the upper and lower surface of the flexible substrate 1 are covered by an insulating layer 3. The thickness of this layer on the wall of the holes 2 is 50 nm. Thereafter, the drain contact D is precipitated over the surface of the lower surface of the polymeric film 1 provided with the insulating layer 3 of 2.5 μm thickness. Thereafter the insulated holes 2 in the polymeric film 1 of filled with CuSCN. This terminates the formation of a semiconductor channel region 4 of a diameter of 100 nm. As a final step, each channel region 4 is covered by a dotted source contact S.

The arrangement in accordance with the invention currently allows for a density of vertical nano-transistors in the flexible polymeric film up to about 10⁷ cm².

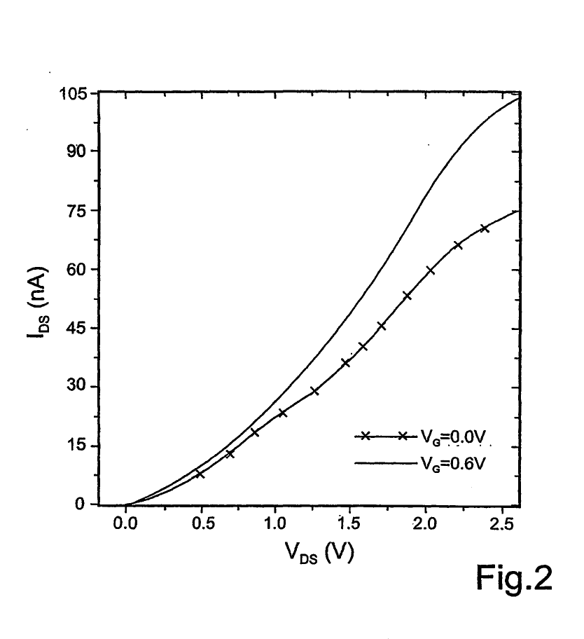

FIG. 2 depicts current-voltage curves (dependency of the current I_{DS}, i.e. the current in the channel between the drain and source contacts, from the voltage V_{DS} measured between the drain and source contacts, without as well as with a negative voltage at the gate), which render the field effect recognizable of an arrangement of about 2,000 nano-transistors in accordance with the invention formed within a polymeric substrate of 8 μm thickness. The metal layer applied to the substrate and forming the gate had a thickness of 110 nm; the diameter of the semiconductor channel was 100 nm.

What is claimed is:

1. A vertical nano-transistor, comprising a source contact (S), a drain contact (D), a gate region (G) and a cylindrical semiconductor channel region (4) between the source (S) and drain (D) contacts, the cylindrical channel region (4) being embedded in a flexible insulating substrate (1) and enclosed by the gate region (G) formed by a metal layer (M) on the flexible insulating substrate (1) and in the upper portion of the channel region (4), such that the gate region (G) and the upper channel region (4) form a coaxial structure and the gate region (G), the semiconductor channel region (4) and the drain contact (D) being arranged in a vertical direction and the gate region (G) being electrically insulated from the source contact (S), the drain contact (D) and the semiconductor channel region (4) and the upper and lower surfaces of the flexible insulating substrate (1) being provided with an electrical insulation (3).

2. The transistor of claim 26, wherein the diameter of the semiconductor channel region is several ten to several hundred nanometers.

3. The transistor of claim 26, wherein the electrical insulation at the upper and lower surface of the flexible substrate is of a thickness of several micrometers.

4. The transistor of claim 26, wherein the electrical insulation in the penetrating holes in the flexible insulating substrate is of a thickness up to several ten nanometers.

5. The transistor of claim 26, wherein the semiconductor channel region comprises a material selected from the group consisting of CuSCN, Ti₂, PbS, ZnO and a compound semiconductor.

6. The transistor of claim 26, wherein the source contact and the drain contact comprise a material selected from the group consisting of Au, Ag, Cu, Ni and Al.

7. The transistor of claim 26, wherein the source contact is structured as a dot.

8. The transistor of claim 26, wherein the thickness of the flexible insulating substrate is several ten micrometers, preferably 10 to 20 μm.

9. A memory arrangement, comprising:
a plurality of vertical nano-transistors in accordance with claim 1;
a matrix; and
means for retaining the plurality of vertical nano-transistors adjacent each other in insulating relationship.

10. A method of fabricating vertical nano-transistors, comprising at least the method steps of:
forming holes in a flexible insulating substrate over the entire thickness thereof;
applying a metal layer forming a vertical gate on the flexible insulating substrate and at the upper portion of the penetrating holes;
applying an insulator material on the upper surface covered by the metal layer, the lower surface of the flexible insulating substrate and the holes over the entire thickness of the flexible insulating substrate;
applying a drain contact on the lower surface of the flexible substrate provided with the insulating material;
filling a semiconductor material into the penetrating holes of the flexible insulating substrate; and
applying a source contact onto the holes filled with semiconductor material.

11. The method of claim 10, wherein the holes in the flexible insulating substrate are formed by ion bombardment and subsequent etching.

12. The method of claim 10, wherein a flexible insulating substrate of a thickness of several ten micrometers is used.

13. The method of claim 10, wherein a polymeric film is used as the flexible insulating substrate.

14. The method of claim 10, wherein the insulator material is applied by vacuum filtration of a polymer solution.

15. The method of claim 10, wherein the gate material is applied by vapor deposition.

16. The method of claim 10, wherein the vapor deposition of the gate material is carried out from above at an angle.

17. The method of claim 10, wherein the drain contact is applied by electro deposition or chemical deposition or vapor deposition.

18. The method of claim 10, wherein the drain contact and the source contact are made from a material selected from the group consisting of Au, Ag, Cu, Ni and Al.

19. The method of claim 10, wherein the semiconductor material is selected from the group consisting of CuSCN, TiO₂, PbS, ZnO and another compound semiconductor.

20. The method of claim 10, wherein the semiconductor material is introduced into the insulated holes by electrochemical bath precipitation.

21. The method of claim 10, wherein the semiconductor material is introduced into the insulated holes by chemical deposition.

22. The method of claim 10, wherein the semiconductor material is introduced into the insulated holes by the ILGAR process.

23. The method of claim 10, wherein the penetrating holes in the flexible insulating substrate are formed with a diameter of several ten to several hundred nanometers.

24. The method of claim 10, wherein the insulation material on the upper surface of the flexible insulating substrate is applied at a thickness of several micrometers.

25. The method of claim 10, wherein the insulation material in the penetrating holes in the flexible insulating substrate is applied at a thickness up to several ten nanometers.

26. A vertical nano-transistor, comprising:
a flexible insulating substrate having an upper surface and a lower surface;
a source contact;
a drain contact;
a cylindrical semiconductor channel region between the source contact and the drain contact and embedded in the flexible insulating substrate;
the source region, the semiconductor channel region and the drain contact being arranged in a vertical direction;
a metal layer on the flexible insulating substrate and on an upper portion of the channel region for forming a gate region;
the cylindrical channel region being enclosed by the gate region such that the gate region and the upper channel portion form a coaxial structure; and
an electrical insulation between the gate region and the source contact, the drain contact and the semiconductor channel region and on the upper and lower surfaces of the flexible insulating substrate.
